(19) United States
(12) Patent Application Publication
(10) Pub. No.: US 2026/0247660 A1
(43) Pub. Date: Aug. 20, 2026

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventor: Takahito KOJIMA, Matsumoto-city (JP)

(73) Assignee: FUJI ELECTRIC CO., LTD., Kawasaki-shi (JP)

(21) Appl. No.: 19/436,400

(22) Filed: Dec. 30, 2025

(30) Foreign Application Priority Data
Feb. 14, 2025 (JP) 2025-022902

(51) Int. Cl. H10D 30/66; H10D 30/01; H10D 62/10

(52) U.S. Cl. CPC H10D 30/668; H10D 30/0297; H10D 30/665; H10D 62/102; H10D 62/124

(57) ABSTRACT

A semiconductor device, including: a semiconductor substrate having a termination region surrounding a periphery of an active region, the termination region having a residual scribe region at an outer periphery of the semiconductor substrate in a plan view, the semiconductor substrate having a main surface; a channel stopper region provided in the semiconductor substrate at the main surface, closer to the active region than is the residual scribe region; a first insulating layer provided on the main surface of the semiconductor substrate in the termination region, closer to the active region than is the residual scribe region, the first insulating layer covering the channel stopper region; and a second insulating layer provided on the main surface of the semiconductor substrate in the termination region, the second insulating layer being in the residual scribe region, the second insulating layer being thinner than the first insulating layer.

### CROSS REFERENCE TO RELATED APPLICATIONS

This application is based upon and claims the benefit of priority of the prior Japanese Patent Application No.2025-022902, filed on February 14, 2025, the entire contents of which are incorporated herein by reference.

### BACKGROUND OF THE INVENTION

### 1. Field of the Invention

Embodiments of the disclosure relate to a semiconductor device and a method of manufacturing a semiconductor device.

### 2. Description of the Related Art

Warpage occurs in a semiconductor wafer during the manufacture of a semiconductor device. When the warpage becomes large, a problem occurs in that the semiconductor wafer cannot be transferred. Japanese Laid-Open Patent Publication No. 2024-148882 describes a technique for suppressing warpage by forming an oxide film having a larger film thickness on the C plane than on the Si plane in a silicon carbide semiconductor wafer. On the other hand, Japanese Laid-Open Patent Publication No. 2021-68741 describes a technique in which, in a dicing region of a semiconductor wafer using a semiconductor having a wider band gap than silicon (Si) as a semiconductor material, an oxide film that is formed by thermal oxidation or the like when a gate insulating film is formed is selectively removed to expose the front surface of the semiconductor wafer.

### SUMMARY OF THE INVENTION

According to an embodiment to of the present disclosure, a semiconductor device includes: a semiconductor substrate, having: an active region through which a main current flows, and a termination region surrounding a periphery of the active region, and having a residual scribe region at an outer periphery of the semiconductor substrate, in a plan view of the semiconductor device, the semiconductor substrate having a main surface; a channel stopper region provided in the semiconductor substrate, at the main surface, the channel stopper being closer to the active region than is the residual scribe region; a first insulating layer provided on the main surface of the semiconductor substrate in the termination region, closer to the active region than is the residual scribe region, the first insulating layer covering the channel stopper region; and

a second insulating layer provided on the main surface of the semiconductor substrate in the termination region, the second insulating layer being in the residual scribe region, the second insulating layer being thinner than the first insulating layer.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a plan view depicting a layout of a semiconductor device according to an embodiment as viewed from a front surface side of a semiconductor substrate.

FIG. 2 is a cross-sectional view depicting a structure along a cutting line A1-A2-A3 in FIG. 1.

FIG. 3 is a cross-sectional view depicting another example of the structure along the cutting line A2-A3 in FIG. 2.

FIG. 4 is a flowchart depicting an outline of a method of manufacturing the semiconductor device according to the embodiment.

FIG. 5 is a cross-sectional view depicting a layout of the semiconductor device according to the embodiment during manufacturing as viewed from a front side of a semiconductor wafer.

FIG. 6 is a cross-sectional view depicting the structure along a cutting line B1-B2 in FIG. 5.

FIG. 7 is a cross-sectional view depicting the structure along the cutting line B1-B2 in FIG. 5.

FIG. 8 is a cross-sectional view depicting a structure of an edge termination region of a semiconductor device of a reference example.

### DETAILED DESCRIPTION OF THE INVENTION

First, problems associated with the conventional techniques are discussed. In the conventional techniques, since a front surface of the semiconductor wafer is exposed during the manufacture of the semiconductor device, there is a concern that the yield may be reduced due to adhesion of foreign matter, generation of a plating film, or the like at the exposed portion of the front surface of the semiconductor wafer.

An outline of an embodiment of the present disclosure is described. (1) A semiconductor device according to one aspect of the present disclosure is as follows. An active region through which a main current flows and a termination region surrounding a periphery of the active region are provided in a semiconductor substrate. In the termination region, a scribe line remaining on an outer periphery of the semiconductor substrate, a channel stopper region provided in the semiconductor substrate, at a first main surface thereof, the channel stopper being closer to the active region than is the scribe line, a first insulating layer provided at the first main surface of the semiconductor substrate, closer to the active region than is the scribe line and covering the channel stopper region, and a second insulating layer provided on the first main surface of the semiconductor substrate, in the scribe line are provided. A thickness of the second insulating layer is smaller than a thickness of the first insulating layer.

According to the above disclosure, the stress applied to the semiconductor wafer, at the first main surface thereof by the first and second insulating layers at the time of fabricating (manufacturing) the semiconductor device is reduced, and the warpage of the semiconductor wafer may be reduced or relaxed in a subsequent manufacturing process. As a result, it is possible to suppress the occurrence of problems (for example, a decrease in alignment accuracy, an increase in thickness variation of a deposited film, and the like) due to the warpage of the semiconductor wafer in a subsequent manufacturing process. Since variations in electrical characteristics among multiple semiconductor chips (semiconductor devices) of a same lot and a same structure may be suppressed, the yield of the semiconductor devices may be improved.

(2) Further, in the semiconductor device according to the present disclosure, in the above-described (1), a thickness of the second insulating layer may be 1/2 or less of a thickness of the first insulating layer.

According to the above disclosure, the thinner the thickness of the second insulating layer is, the more the warpage of the semiconductor wafer may be reduced or alleviated at the time of manufacturing the semiconductor device.

(3) In the semiconductor device according to (1) or (2), the second insulating layer may have a thickness of 8000Å or less.

According to the above disclosure, the thinner the thickness of the second insulating layer is, the more the warpage of the semiconductor wafer may be reduced or alleviated at the time of manufacturing the semiconductor device.

(4) In the semiconductor device according to any one of (1) to (3), an outer peripheral end of the channel stopper region may be located at an inner peripheral end of the scribe line.

According to the above disclosure, increases of a non-operating region closer to a chip end than is the channel stopper region may be suppressed, the non-operating region not functioning as the semiconductor device.

(5) In the semiconductor device according to any one of (1) to (4) described above, the semiconductor device may further include a voltage withstanding structure provided in the semiconductor substrate, at the first main surface thereof in the termination region, the voltage withstanding structure being apart from the channel stopper region and provided closer to the active region than is the channel stopper region, and the first insulating layer may cover the voltage withstanding structure and the channel stopper region.

According to the above disclosure, it is possible to secure a predetermined breakdown voltage in the semiconductor substrate by the voltage withstanding structure and the channel stopper region, and to secure a predetermined breakdown voltage at an upper surface (front surface of the semiconductor substrate) of the voltage withstanding structure and the channel stopper region by the first insulating layer.

(6) A method of manufacturing a semiconductor device according to one aspect of the present disclosure is a method of manufacturing a semiconductor device including a semiconductor substrate having an active region through which a main current flows and a termination region surrounding a periphery of the active region, the method being as follows. A first step of forming a channel stopper region in a semiconductor wafer, at a first main surface in a region corresponding to the termination region of a chip region of the semiconductor wafer is performed. A second step of forming an insulating layer on the first main surface of the semiconductor wafer is performed. A third step of cutting the chip region from the semiconductor wafer into the semiconductor substrate the semiconductor wafer by cutting along a scribe line surrounding a periphery of the chip region is performed. At the second step, the insulating layer including a first insulating layer covering the channel stopper region and a second insulating layer covering the scribe line is formed, and a thickness of the second insulating layer is made smaller than a thickness of the first insulating layer.

According to the above disclosure, the stress applied to the semiconductor wafer, at the first main surface thereof is reduced by the first and second insulating layers, and the warpage of the semiconductor wafer may be reduced or relaxed in a subsequent manufacturing process. Thus, even when the semiconductor wafer is warped, a subsequent manufacturing process may be continued without discarding the semiconductor wafer and thus, the yield of the semiconductor device may be improved.

(7) In the method of manufacturing a semiconductor device according to the present disclosure, in (6) described above, at the second step, multiple insulating films may be stacked on the first main surface of the semiconductor wafer, and the first insulating layer may be formed by all the stacked insulating films and the second insulating layer may be formed by some of the stacked insulating films.

According to the above disclosure, the thicknesses of the first and second insulating layers may be easily set.

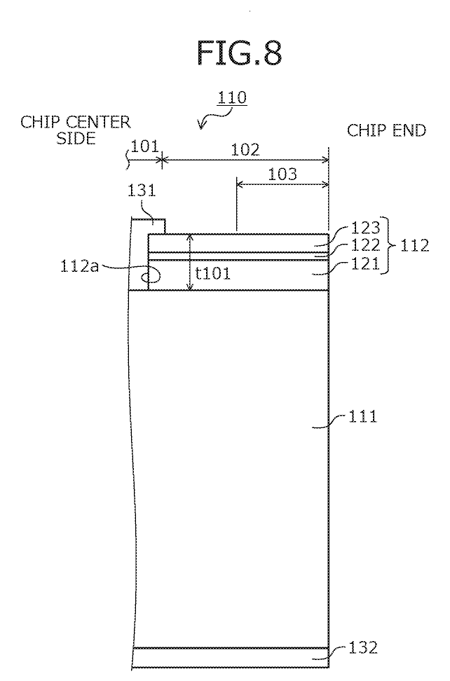

Findings underlying the present disclosure are discussed. First, a structure of a semiconductor device of a reference example will be described. FIG. 8 is a cross-sectional view depicting a structure of an edge termination region of the semiconductor device of the reference example. A semiconductor device 110 of the reference example depicted in FIG. 8 includes, in an edge termination region 102 of a semiconductor substrate (semiconductor chip) 111, a residual scribe region 103 in an outer periphery of the semiconductor substrate 111 and an insulating layer 112 covering an entire front surface of the semiconductor substrate 111. The semiconductor substrate 111 includes an active region 101 through which a main current (drift current) of the semiconductor device 110 flows, and an edge termination region 102 between the active region 101 and an end portion (chip end) of the semiconductor substrate 111. The edge termination region 102 surrounds the periphery of the active region 101.

The residual scribe region 103 is a remaining portion of a cutting margin (scribe line of the semiconductor wafer) left when each semiconductor chip (semiconductor substrate 111) is cut from the semiconductor wafer. The residual scribe region 103 is provided over an entire outer periphery of the semiconductor substrate 111. The insulating layer 112 is formed by stacking a field oxide film 121, a gate insulating film 122, and an interlayer insulating film 123 in this order, and covers the voltage withstanding structure (not depicted) of the edge termination region 102 and the channel stopper region (not depicted). A thickness t101 of the insulating layer 112 is relatively thick, for example, about 15000Å, and is substantially constant over the entire region of the edge termination region 102 up to the chip end.

When a plating film is formed on a surface electrode 131 on the front surface of the semiconductor substrate 111, the insulating layer 112 is also formed on a scribe line of the semiconductor wafer (not depicted) so that the front surface of the semiconductor wafer is not exposed during plating processing on the surface electrode 131 (metal layer embedded in a contact hole 112a of the insulating layer 112), thereby preventing the plating film from adhering to the front surface of the semiconductor wafer. However, it has been confirmed experimentally by the present inventors that the warpage of the semiconductor wafer increases due to the relatively large thickness t101 of the insulating layer 112 formed over the scribe line of the semiconductor wafer.

Warping of the semiconductor wafer refers to, for example, a state in which the entire semiconductor wafer has, in a cross-sectional view, a substantially arc-shaped that is curved so as to protrude in a convex shape toward the front side or the back side in a direction substantially orthogonal to the main surface with one location (a predetermined point or a predetermined area portion) of the main surface (the front surface and the back surface) of the semiconductor wafer as an apex. In addition, as a case where warpage occurs in the semiconductor wafer, there is a saddle-shaped warpage (wave shape) state. The warpage amount of the semiconductor wafer is a distance between an apex of the main surface of the semiconductor wafer in a state of being warped and curved in a direction orthogonal to the main surface of the semiconductor wafer in a substantially flat state before warpage occurs and a location (specifically, an end portion of the semiconductor wafer) farthest from the apex of the main surface of the semiconductor wafer. That is, the warpage amount of the semiconductor wafer is the height (indicated by the arrow (the height of the arc)) of the semiconductor wafer having a substantially arc-shaped cross section.

For example, on the semiconductor wafer, for example, multiple chip regions to be semiconductor chips (semiconductor substrates 111) are arranged in a matrix, and scribe lines are provided in a lattice shape surrounding each chip region. When the semiconductor device 110 is fabricated (manufactured) using a semiconductor wafer containing silicon carbide (SiC), which is expected as a next-generation semiconductor material to replace silicon (Si), and the insulating layer 112 is formed with a thickness t101 of about 15000Å on the entire front surface of the semiconductor wafer so as to cover the entire area of the scribe line, the amount of warpage of the semiconductor wafer becomes about 150 μm or more after etching for patterning a metal layer formed on the entire front surface of the semiconductor wafer and leaving a portion to be the surface electrode 131.

In addition, warpage occurs in the semiconductor wafer due to an adverse effect of heat associated with ion implantation into the semiconductor wafer. Even when the insulating layer 112, a polysilicon (poly-Si) layer such as a wiring layer, and a metal layer such as the surface electrodes 131 and 132 are formed on the surface of the semiconductor wafer, a difference in stress occurs between the front surface side and the back surface side of the semiconductor wafer due to a difference in the thermal expansion coefficients among these layers and the semiconductor wafer and thus, warpage occurs in the semiconductor wafer. Even when the semiconductor wafer is ground from the back surface to be thinned to a predetermined thickness, the balance of the stress between the front surface side and the back surface side of the semiconductor wafer is lost and thus, warpage occurs in the semiconductor wafer. The warpage generated in the semiconductor wafer is cumulative and increases as the manufacturing process of the semiconductor device 110 progresses.

When the amount of warpage of the semiconductor wafer increases, there is a possibility that the semiconductor wafer cannot be placed on a stage of a semiconductor manufacturing equipment or a crack occurs in the semiconductor wafer, and it becomes difficult to input the semiconductor wafer to a subsequent manufacturing process, thereby decreasing the yield of products. The yield is a ratio of the number of actually obtained products (semiconductor devices satisfying a predetermined design condition) to a calculated value of the number of semiconductor devices (semiconductor chips cut from the semiconductor wafer) to be obtained from a semiconductor wafer input to the manufacturing process. As a result of intensive studies, the present inventors have found that the amount of warpage of the semiconductor wafer varies depending on the thickness of the insulating layer 112 on the scribe lines of the semiconductor wafer. The present disclosure has been made based on experimental findings and theoretical considerations.

The present embodiment improves the yield by reducing the warpage of the semiconductor wafer.

Embodiments of a semiconductor device and a method of manufacturing a semiconductor device according to the present disclosure will be described in detail below with reference to the accompanying drawings. In the present specification and the accompanying drawings, layers and regions prefixed with n or p mean that majority carriers are electrons or holes, respectively. Further, + and − appended to n and p mean that the dopant concentration is higher or lower, respectively, than layers and regions without + and −. In the following description of the embodiments and the accompanying drawings, identical components are denoted by the same reference numerals, and redundant description thereof will be omitted.

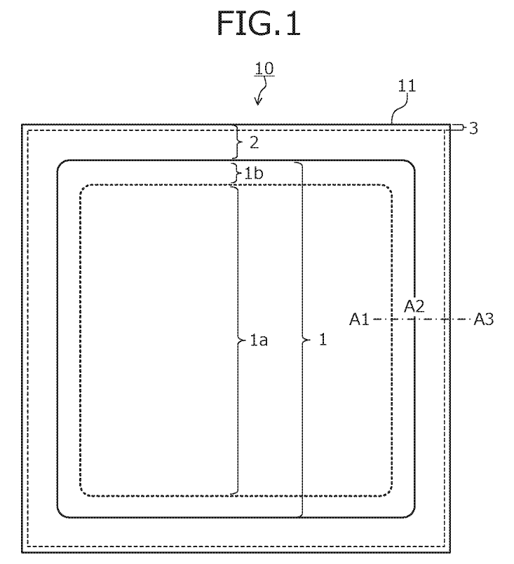

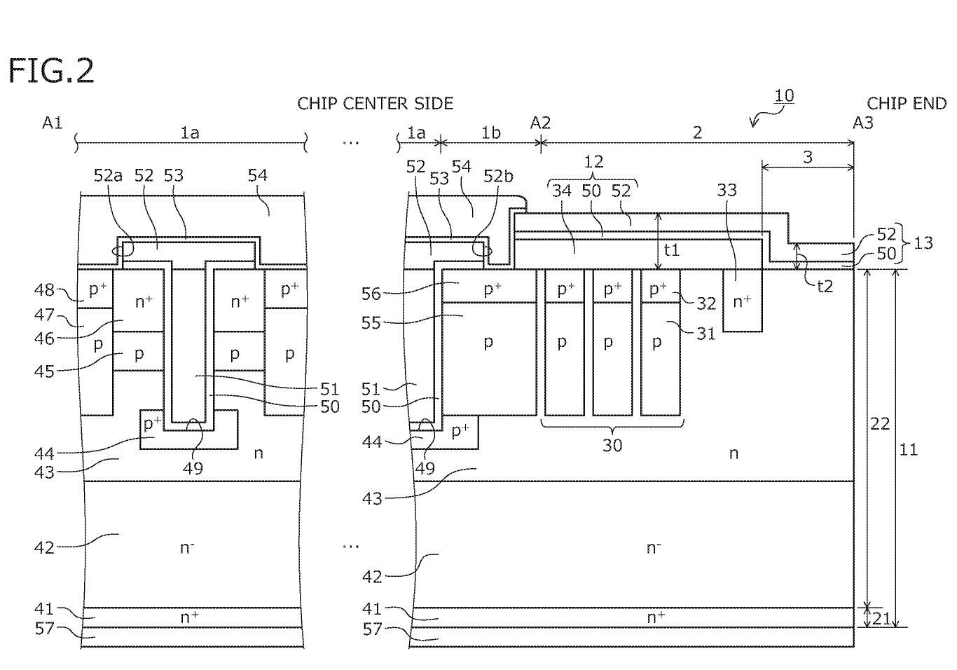

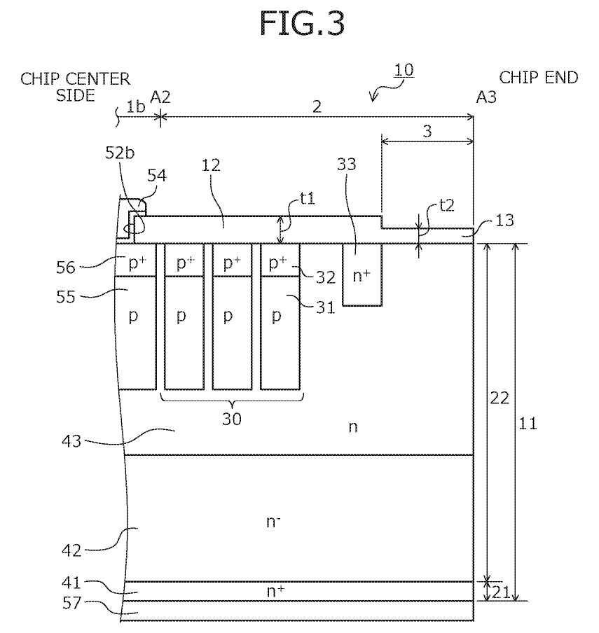

A semiconductor device according to an embodiment solving the above-described problems is described. FIG. 1 is a plan view depicting a layout of a semiconductor device according to an embodiment as viewed from a front surface side of a semiconductor substrate. FIG. 2 is a cross-sectional view depicting a structure along a cutting line A1-A2-A3 in FIG. 1. FIG. 3 is a cross-sectional view depicting another example of the structure along the cutting line A2-A3 in FIG. 2. The configuration of the edge termination region 2 depicted in FIG. 3 is the same as that depicted in FIG. 2 except for the insulating layers 12 and 13. A semiconductor device 10 according to the embodiment depicted in FIGS. 1 and 2 includes, in an edge termination region 2 of a semiconductor substrate (semiconductor chip) 11, a residual scribe region 3 in an outer periphery of the semiconductor substrate 11 and insulating layers (first and second insulating layers) 12 and 13 covering a front surface of the semiconductor substrate 11 and having different thicknesses t1 and t2.

As a material (semiconductor material) of the semiconductor substrate 11, a compound semiconductor such as silicon carbide (SiC) or gallium nitride (GaN) may be used. For example, a semiconductor device containing SiC as a semiconductor material has various advantages as compared with a semiconductor device containing silicon (Si) as a semiconductor material. For example, the semiconductor device containing SiC as a semiconductor material may reduce the thickness of the semiconductor substrate 11 while maintaining the breakdown voltage to thereby reduce the on-resistance to about several one hundredths and may be used in a high-temperature environment (for example, about 200°C or higher). This is due to the characteristics of the material itself, SiC has a band gap about three times larger than that of Si and a dielectric breakdown electric field strength nearly one order of magnitude larger than that of Si. The withstand voltage is an upper limit voltage at which the semiconductor device does not malfunction or break down at the usage voltage.

As depicted in FIG. 1, the semiconductor substrate 11 has an active region 1 and an edge termination region 2. The active region 1, in a plan view, has a substantially rectangular shape and is provided substantially at a center (chip center) of the semiconductor substrate 11. In a center portion 1a of the active region 1, multiple cells (functional units of a device element) each having the same structure are disposed connected in parallel. The center portion 1a of the active region 1 has, for example, a substantially rectangular planar shape in a plan view and is a region through which a main current (drift current) flows when the semiconductor device 10 is on. The outer peripheral portion 1b of the active region 1 surrounds the center portion 1a of the active region 1 in a substantially rectangular shape. A p-type peripheral region 55 (see FIG. 2) described later is provided in the peripheral portion 1b of the active region 1. The active region 1 is a portion on an inner side (chip center side) from the outer peripheral end of the p-type outer peripheral region 55.

As the semiconductor device 10 containing SiC as a semiconductor material, for example, a Schottky barrier diode (SBD) and a vertical metal oxide semiconductor field effect transistor (MOSFET) having a planar gate structure or a trench gate structure have been commercialized. The semiconductor device 10 may be an insulated gate bipolar transistor (IGBT). Here, a case where the semiconductor device 10 is a vertical MOSFET having a trench gate structure will be described as an example.

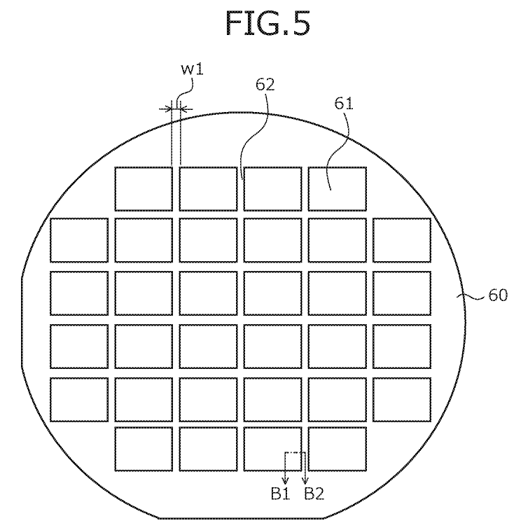

The edge termination region 2 is a region between the active region 1 and the chip end, the edge termination region 2 surrounds the periphery of the active region 1 in a substantially rectangular shape, in a plan view. For example, a field limiting ring (FLR) or a junction termination (JTE) may be formed in the edge termination region. A predetermined voltage withstanding structure 30 (see FIG. 2) such as a termination extension structure or a guard ring is disposed. The voltage withstanding structure 30 has a function of relaxing an electric field applied to the inside (surface region on the front surface side) of the semiconductor substrate 11 and sustaining a breakdown voltage. The edge termination region 2 has a residual scribe region 3 in the entire outer periphery of the semiconductor substrate 11. The residual scribe region 3 is a remaining portion of a cutting margin (scribe lines 62: see FIG. 5 described later), remaining when a semiconductor chip (semiconductor substrate 11) is cut out from a semiconductor wafer 60 by a dicing blade or the like.

As depicted in FIG. 2, the semiconductor substrate 11 is formed by, for example, growing, by epitaxy, an epitaxial layer 22 of the same material as an n⁺-type starting substrate 21, the epitaxial layer 22 being grown on a front surface of the n⁺-type starting substrate (bulk substrate) 21. The semiconductor substrate 11 has, as a front surface, a first main surface on the epitaxial layer 22 side and, as a back surface, a second main surface on the n⁺-type starting substrate 21 side. Here, a case where the material of the semiconductor substrate 11 is SiC will be described as an example. SiC has an extremely small dopant diffusion coefficient as compared with Si, and it is difficult for the dopant to reach deep from the ion implantation surface in SiC by ion implantation with normal acceleration energy (for example, about 900KeV or less). Therefore, a diffused region of a predetermined conductivity type dopant ion-implanted at a deep position from the front surface of the semiconductor substrate 11 is formed by dividing the epitaxy for the epitaxial layer into multiple stages and performing ion implantation into the epitaxial layer grown at each stage and stacked.

When the material of the semiconductor substrate 11 is SiC, a diffused region of a dopant of a predetermined conductivity type may be formed in SiC by combining ion implantation with normal acceleration energy and ion implantation with high acceleration energy (for example, about 1MeV or more) capable of implanting an dopant to a deep position from an ion implantation surface. In this case or when the material of the semiconductor substrate 11 is Si, the semiconductor substrate 11 may be formed of only a bulk substrate. In a case where the semiconductor substrate 11 is formed of only a bulk substrate, since epitaxial growth is not performed, process control of an epitaxial growth equipment is not required, and crystal defects due to epitaxial growth are not formed in the semiconductor substrate 11. Therefore, characteristics variations of the semiconductor device 10 may be suppressed. In addition, the maintenance cost of the epitaxial growth equipment may be reduced.

The n⁺-type starting substrate 21 constitutes an n⁺-type drain region 41. The epitaxial layer 22 constitutes an n⁻-type drift region 42. A trench gate structure including p-type base regions 45, n⁺-type source regions 46, base contact regions 47 and 48, trenches 49, a gate insulating film 50, and gate electrodes 51 is provided in the semiconductor substrate 11, at the front surface thereof, in the center portion 1a of the active region 1. The n⁻-type drift region 42 is a portion of the epitaxial layer 22 excluding the trench gate structure, and an n-type current spreading region 43, p⁺-type regions 44, a p-type outer peripheral region 55, a p⁺-type outer peripheral contact region 56, the voltage withstanding structure 30 (p-type regions 31 and a p⁺-type regions 32), and a channel stopper region 33, which will be described later. Between the n⁺-type starting substrate 21 and these regions, the n⁻-type drift region 42 is provided in the active region 1 and the edge termination region 2 and reaches the chip end.

The p-type base regions 45, the n⁺-type source regions 46, the base contact regions 47 and 48, the n-type current spreading region 43, the p⁺-type regions 44, the p-type outer peripheral region 55, the p⁺-type outer peripheral contact region 56, the p-type regions 31, the p⁺-type regions 32, and the channel stopper region 33 are diffused regions of dopants of predetermined conductivity types selectively formed in the epitaxial layer 22 by ion implantation. The p-type base regions 45 and the p-type base contact regions 47 are each selectively provided between the front surface of the semiconductor substrate 11 and the n⁻-type drift region 42 in the center portion 1a of the active region 1. The n⁺-type source regions 46 are provided in contact with the p-type base regions 45 in the entire region between the front surface of the semiconductor substrate 11 and the p-type base regions 45. The p⁺-type base contact regions 48 are provided in contact with the p-type base contact regions 47 in the entire region between the front surface of the semiconductor substrate 11 and the p-type base contact regions 47.

The p-type base regions 45 and the n⁺-type source regions 46 face the gate electrodes 51 via the gate insulating film 50 at the sidewalls of the trenches 49. The p-type base contact regions 47 and the p⁺-type base contact regions 48 are provided apart from the trenches 49 and face the sidewalls of the trenches 49 via the p-type base regions 45 and the n⁺-type source regions 46, respectively. The n⁺-type source regions 46 may terminate at a position deeper toward the n⁺-type drain region 41 than are the p⁺-type base contact regions 48. The p-type base contact regions 47 may terminate at a position deeper toward the n⁺-type drain region 41 than are the p-type base regions 45. The n⁺-type source regions 46 and the p⁺-type base contact regions 48 are in contact with a barrier metal 53 on the front surface of the semiconductor substrate 11. The p⁺-type base contact regions 48 may be omitted, and the p-type base contact regions 47 may be in contact with the barrier metal 53 on the front surface of the semiconductor substrate 11.

The n-type current spreading region 43 is selectively provided at a position deeper toward the n⁺-type drain region 41 than are bottoms of the trenches 49, between the n⁻-type drift region 42 and the p-type base regions 45 and the p-type base contact regions 47. The n-type current spreading region 43 is a so-called current spreading layer that reduces carrier spreading resistance. The n-type current spreading region 43 is in contact with the n⁻-type drift region 42, the p⁺-type regions 44, the p-type base regions 45, and the p-type base contact regions 47, and faces the gate electrodes 51 via the gate insulating film 50 at the sidewalls of the trenches 49. The n-type current spreading region 43 may extend to the outer peripheral portion 1b of the active region 1 or the edge termination region 2, or may reach the chip end. The n⁻-type drift region 42 may be in contact with the p-type base regions 45 and the p-type base contact regions 47 and the n-type current spreading region 43 may be omitted.

The p⁺-type regions 44 are selectively provided closer to the n⁺-type drain region 41 than are the bottoms of the trenches 49, between the n⁻-type drift region 42 and the p-type base regions 45. The p⁺-type regions 44 are provided apart from the p-type base regions 45 and the p-type base contact regions 47, and face the bottoms of the trenches 49 in the depth direction. The p⁺-type regions 44 have a function of relaxing electric field applied to the gate insulating film 50 at the bottoms of the trenches 49. The p⁺-type regions 44 is partially coupled to, for example, the p-type base contact regions 47 and the p-type outer peripheral region 55, and is fixed to the potential of the source electrode. The p⁺-type regions 44 may be in contact with the gate insulating film 50 at the bottoms of the trenches 49, or may further extend toward the n⁺-type source regions 46 along the sidewalls of the trenches 49. The p⁺-type regions 44 may be apart from the trenches 49. The n-type current spreading region 43 may be interposed between the p⁺-type regions 44 and the n^{−}-type drift region 42.

The trenches 49 penetrate through the n⁺-type source regions 46 and the p-type base regions 45 in the depth direction from the front surface of the semiconductor substrate 11, and terminate in the n-type current spreading region 43 (the n⁻-type drift region 42 in a case where the n-type current spreading region 43 is omitted) or terminates in the p⁺-type regions 44 via the n-type current spreading region 43. The trenches 49 may terminate at a position deeper toward the n⁺-type drain region 41 than are the p-type base contact regions 47. In the trenches 49, the gate insulating film 50 is provided along inner walls (sidewalls and bottom surface) of the trenches 49. The gate insulating film 50 extends from the sidewalls of the trenches 49 onto the front surface of the semiconductor substrate 11, reaches the chip end, and covers the entire front surface of the semiconductor substrate 11. The gate electrodes 51 are provided on the gate insulating film 50 in the trenches 49 so as to be embedded in the trenches 49.

In the outer peripheral portion 1b of the active region 1, the p-type outer peripheral region 55 is provided in the entire region between the front surface of the semiconductor substrate 11 and the n⁻-type drift region 42. The p-type outer peripheral region 55 terminates at a position shallower (closer to the n⁺-type source regions 46) than are the trenches 49. The p-type outer peripheral region 55 may terminate at a position deeper toward the n⁺-type drain region 41 than are the p-type base regions 45. The p-type outer peripheral region 55 surrounds the center portion 1a of the active region 1 in a substantially rectangular shape, in a plan view. The p⁺-type outer peripheral contact region 56 is provided in contact with the p-type outer peripheral region 55 in the entire region between the front surface of the semiconductor substrate 11 and the p-type outer peripheral region 55. The p⁺-type outer peripheral contact region 56 is in contact with the barrier metal 53 on the front surface of the semiconductor substrate 11. The p-type outer peripheral region 55 may be in contact with the barrier metal 53 on the front surface of the semiconductor substrate 11 and the p⁺-type outer peripheral contact region 56 may be omitted.

An interlayer insulating film 52 is provided on the entire front surface of the semiconductor substrate 11 via the gate insulating film 50 so as to cover the gate electrodes 51. The interlayer insulating film 52 is, for example, a single-layer film of a silicon oxide (SiO₂₎ film such as a boron phosphosilicate glass (BPSG), a phosphosilicate glass (PSG), boron silicate glass (BSG), or a non-doped silicate glass (NSG), or a silicon nitride (SixNy, where x and y are positive numbers) film, or a stacked film of two or more of these films. A SiO₂ film such as a high temperature oxide (HTO) film may be provided in the entire region between the gate insulating film 50 and the interlayer insulating film 52. Contact holes 52a and 52b penetrating through the interlayer insulating film 52 and the gate insulating film 50 in the depth direction are provided.

The barrier metal 53 is in ohmic contact with the front surface of the semiconductor substrate 11 in the contact holes 52a and 52b. The barrier metal 53 is, for example, a titanium nitride (TiN) film, a titanium (Ti) film, or a stacked film thereof. The surface electrode 54 at the front surface of the semiconductor substrate 11 is provided on the interlayer insulating film 52 in the active region 1 so as to be embedded in the contact holes 52a and 52b. The surface electrode 54 is electrically connected to the p-type base regions 45, the n⁺-type source regions 46, and the base contact regions 47 and 48 via the barrier metal 53 in the contact holes 52a. The surface electrode 54 is electrically connected to the p-type outer peripheral region 55 and the p⁺-type outer peripheral contact region 56 via the barrier metal 53 in the contact hole 52b. A barrier metal 53 may be interposed between the surface electrode 54 and the interlayer insulating film 52.

The surface electrode 54 contains, for example, aluminum (Al), aluminum-silicon (Al—Si), aluminum-copper (Al—Cu), copper (Cu), or the like. The surface electrode 54 and the barrier metal 53 function as a source electrode. The front surface of the semiconductor substrate 11 is protected by an uppermost surface protective film (not depicted) containing a polyimide. A portion of the surface electrode 54 exposed in the opening of the surface protection film (passivation film) functions as a source pad (electrode pad). A plating film (not depicted) may be formed on the surface of the source pad. The plating film imparts solder wettability to the surface of the source pad. The plating film on the surface of the source pad has a function of enhancing adhesion between the source pad and a metal wiring such as a bonding wire when the metal wiring is soldered to the surface of the source pad.

In the edge termination region 2, multiple (three in FIG. 2) p-type regions 31 configuring the voltage withstanding structure 30 are selectively provided between the front surface of the semiconductor substrate 11 and the n⁻-type drift region 42. The p-type regions 31 are provided apart from the p-type outer peripheral region 55 and the p⁺-type outer peripheral contact region 56 and outside these regions (on the chip end side), the p-type regions 31 concentrically surround the periphery of the active region 1, in a plan view. The p⁺-type regions 32 are provided in contact with the p-type regions 31 in the entire region between the front surface of the semiconductor substrate 11 and the p-type regions 31. The p⁺-type regions 32 are exposed at the front surface of the semiconductor substrate 11. For example, the p-type regions 31 and the p⁺-type regions 32 are formed concurrently with the p-type outer peripheral region 55 and the p⁺-type outer peripheral contact region 56, respectively. The p-type regions 31 may reach the front surface of the semiconductor substrate 11 and the p⁺-type regions 32 may be omitted.

FIG. 2 depicts the voltage withstanding structure 30 of an FLR structure (guard ring structure) in which the p-type regions 31 (FLR) having the same dopant concentration and a floating potential are disposed in a concentric pattern so as to surround the periphery of the active region 1 and to be apart from each other. Between the n⁻-type drift region 42 and the p-type outer peripheral region 55 and between the p-type regions 31, the n-type current spreading region 43 may extend from the center portion 1a of the active region 1 and be in contact with these regions. The n-type current spreading region 43 (the n⁻-type drift region 42 in a case where the n-type current spreading region 43 is omitted) extends between the p-type outer peripheral region 55 and an innermost one of the p-type regions 31 and between the p-type regions 31 adjacent to each other, and reaches the front surface of the semiconductor substrate 11 by passing between the p⁺-type outer peripheral contact region 56 and the innermost p⁺-type regions 32 and between the p⁺-type regions 32 adjacent to each other.

The edge termination structure 30 may be a JTE structure (for example, a multi-zone JTE structure or a spatially modulated JTE structure). The multi-zone JTE structure is a structure in which, in a plan view, three or more p-type regions fixed to the potential of the source electrode are disposed adjacent to each other in a concentric pattern surrounding the periphery of the active region 1, the p-type regions being disposed in descending order of dopant concentration in a direction from the active region 1 to the chip end. The spatial modulation JTE structure is an improved structure of the JTE structure, and is a structure in which a p-type spatial modulation region having a dopant concentration distribution spatially equivalent to an intermediate dopant concentration between two p-type regions is disposed adjacently between the two p-type regions, and the dopant concentration distribution of the entire JTE structure is gradually decreased in an outward direction (in a direction to the chip end). The spatial modulation region is formed by arranging two p-type sub- regions repeatedly alternating each other and having substantially the same dopant concentration as that of the adjacent p-type regions on each side of the spatial modulation region in a predetermined pattern concentrically surrounding the periphery of the active region 1.

In the edge termination region 2, the channel stopper region 33 of n⁺-type or p⁺-type and having a floating potential is selectively provided between the front surface of the semiconductor substrate 11 and the n⁻-type drift region 42. The channel stopper region 33 is provided outside the edge termination structure 30 so as to be apart from the edge termination structure 30, the channel stopper region 33 surrounding a periphery of the edge termination structure 30. The channel stopper region 33 is provided closer to the active region than is the residual scribe region 3 and does not reach the chip end. The channel stopper region 33 is exposed at the front surface of the semiconductor substrate 11. The outer peripheral end of the channel stopper region 33 is preferably located at the inner peripheral end of the residual scribe region 3. A portion of the semiconductor substrate 11 outside the channel stopper region 33 is a non-operating region that does not function as the semiconductor device 10. Since the outer peripheral end of the channel stopper region 33 is located at the inner peripheral end of the residual scribe region 3, an increase in the surface area of the non-operating region of the semiconductor substrate 11 may be suppressed.

In the center portion 1a of the active region 1, the n-type current spreading region 43 may be between and contact with the n⁻-type drift region 42 and the channel stopper region 33 and extend to the chip end. The channel stopper region 33 is surrounded by the n-type current spreading region 43 (the n⁻-type drift region 42 when the n-type current spreading region 43 is omitted). The n-type current spreading region 43 reaches the front surface of the semiconductor substrate 11 between the channel stopper region 33 and an outermost one of the p-type regions 31 and an outermost one of the p⁺-type regions 32, and between the channel stopper region 33 and the chip end. The channel stopper region 33 has a function of suppressing a depletion layer from reaching the chip end when the semiconductor device 10 turns off, the depletion layer spreading from pn junctions formed by the p-type regions 31 of the voltage withstanding structure 30. The channel stopper region 33 is formed concurrently with the n⁺-type source regions 46, for example. A field plate and a channel stopper electrode are omitted.

In the edge termination region 2, an entire area of the front surface of the semiconductor substrate 11 closer to the active region 1 than is the residual scribe region 3 is covered with an insulating layer 12, and an entire area of the front surface of the semiconductor substrate 11 in the residual scribe region 3 is covered with an insulating layer 13. The insulating layer 12 has a function of covering the entire upper surfaces of the voltage withstanding structure 30 and the channel stopper region 33 (the front surface of the semiconductor substrate 11) and ensuring a predetermined breakdown voltage at the upper surfaces of the voltage withstanding structure 30 and the channel stopper region 33. The insulating layer 12 may extend to the outer peripheral portion 1b of the active region 1 and cover the outer peripheral portion of the p⁺-type outer peripheral contact region 56 (the p-type outer peripheral region 55 when the p⁺-type outer peripheral contact region 56 is omitted). When the insulating layer 12 has a stacked structure of multiple insulating films (for example, the field oxide film 34, the gate insulating film 50, and the interlayer insulating film 52), configuration may be such that only some of the insulating films (for example, the gate insulating film 50 and the interlayer insulating film 52) constituting the insulating layer 12 extend to the outer peripheral portion 1b of the active region 1.

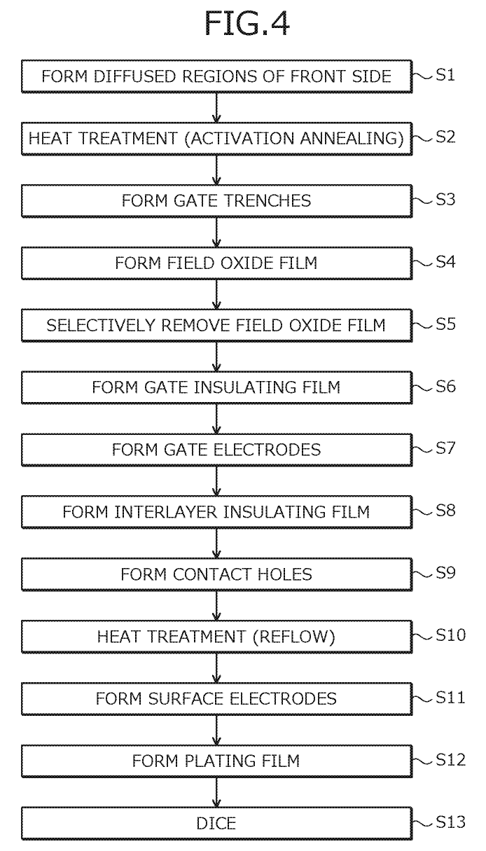

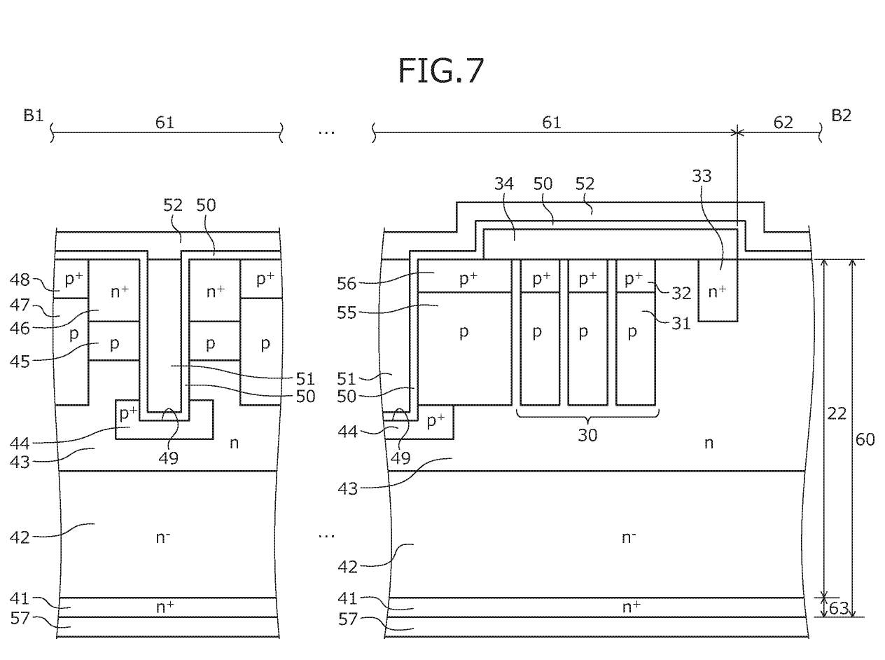

The insulating layer 13 is a remaining portion of an insulating layer (for example, the gate insulating film 50 and an interlayer insulating film 52: see FIG. 7 described later) formed on the front surface of the semiconductor wafer 60 in the scribe lines 62 of the semiconductor wafer 60 at the time of manufacturing the semiconductor device 10. A thickness t2 of the insulating layer 13 is thinner than a thickness t1 of the insulating layer 12 and is appropriately set so that the magnitude of imbalance of the stress between the front side and the back side of the semiconductor wafer 60 after a later-described process at step S11 (see FIG. 4) during the manufacture of the semiconductor device 10 is small. Specifically, the thickness t2 of the insulating layer 13 may be, for example, about 1/2 or less of the thickness t1 of the insulating layer 12. More specifically, the thickness t2 of the insulating layer 13 may be, for example, about 8000Å or less. The thickness t2 of the insulating layer 13 may be as thin as possible within a range in which the front surface of the semiconductor substrate 11 is not exposed (that is, 0Å<t2), and may be, for example, about 50Å or more.

The difference in thickness between the insulating layer 12 and the insulating layer 13 is preferably as large as possible within a range that does not deteriorate, for example, the coverage of an etching mask used at the time of patterning the surface electrode 54 or the coverage of a surface protective film serving as the uppermost layer of the front surface of the semiconductor substrate 11. The insulating layer 12 may have a stacked structure including all the insulating films stacked on the front surface of the semiconductor substrate 11 in the edge termination region 2, and the insulating layer 13 may have a stacked structure (see FIG. 2) or a single-layer structure including some of the insulating films stacked at the front surface of the semiconductor substrate 11 in the edge termination region 2. In this case, the thicknesses t1 and t2 of the insulating layers 12 and 13 may be easily set by the number of stacked insulating films. Specifically, for example, the insulating layer 12 has a stacked structure in which a field oxide film 34, the gate insulating film 50, and the interlayer insulating film 52 are stacked in this order (FIG. 2). The field oxide film 34 is provided in an entire region between the gate insulating film 50 and the front surface of the semiconductor substrate 11, closer to the active region 1 than is the residual scribe region 3 in the edge termination region 2, and the residual scribe region 3 being free of the field oxide film 34.

The gate insulating film 50 and the interlayer insulating film 52 are stacked in this order on the field oxide film 34. The gate insulating film 50 and the interlayer insulating film 52 extend outward along the front surface of the field oxide film 34, reach the chip end, and cover the entire front surface of the semiconductor substrate 11 in the residual scribe region 3. The gate insulating film 50 and the interlayer insulating film 52 covering the front surface of the semiconductor substrate 11 in the residual scribe region 3 constitute the insulating layer 13. The thickness t1 of the insulating layer 12 is, for example, about 15000Å. The thickness of the field oxide film 34 is larger than the thicknesses of the gate insulating film 50 and the interlayer insulating film 52. Since the insulating layer 13 does not include the field oxide film 34, the thickness t2 of the insulating layer 13 is, for example, about 8000Å or less. The thickness t2 of the insulating layer 13 may be made thinner than the thickness t1 of the insulating layer 12 by removing a portion of any insulating film (here, the field oxide film 34) of the insulating films stacked on the front surface of the semiconductor substrate 11 in the edge termination region 2, the portion that is on the residual scribe region 3 as described above.

While the thickness t2 of the insulating layer 13 may be partially increased due to, for example, a step between the upper surface of the field oxide film 34 and the front surface of the semiconductor substrate 11 (see FIG. 2), preferably, the thickness t2 may be substantially constant over the entire area of the residual scribe region 3 (see FIG. 3). By making the thickness t2 of the insulating layer 13 substantially constant, the stress applied to the front side of the semiconductor wafer 60 by the insulating layer 13 may be reduced as compared with a case where the thickness t2 of the insulating layer 13 is partially increased. The insulating layers 12 and 13 may have a single-layer structure of one insulating film with the thickness t2 being relatively small in the residual scribe region 3 (see FIG. 3). For example, the thickness t2 of the insulating layer 13 may be adjusted by an additional step of etching performed only to the insulating layer 13 to make the thickness t2 of the insulating layer 13 substantially constant or to further reduce the thickness t2 of the insulating layer 13. The front surface electrode 57 provided on the entire back surface of the semiconductor substrate 11 (back surface of the n⁺-type starting substrate 21) is a drain electrode and is electrically connected to the n⁺-type drain region 41 (n⁺-type starting substrate 21).

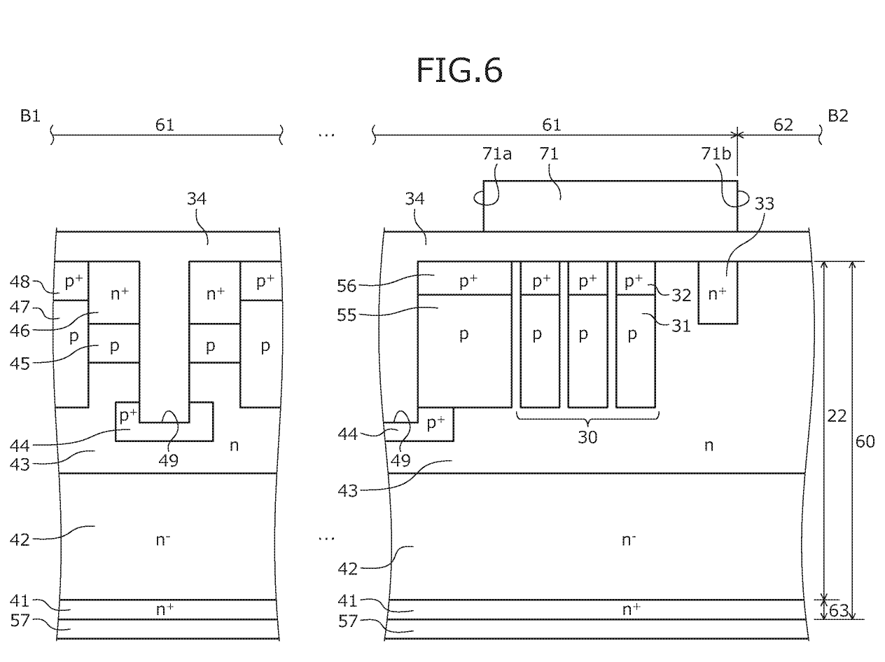

A method of manufacturing the semiconductor device 10 according to the embodiment will be described. FIG. 4 is a flowchart depicting an outline of the method of manufacturing the semiconductor device according to the embodiment. FIG. 5 is a cross-sectional view depicting a layout of the semiconductor device according to the embodiment during manufacturing as viewed from the front side of the semiconductor wafer. FIGS. 6 and 7 are cross-sectional views depicting the structure along a cutting line B1-B2 in FIG. 5. FIGS. 6 and 7 depict one chip region 61 and a scribe line 62 adjacent to the chip region 61 taking the structure of the edge termination region 2 depicted in FIG. 2 as an example. The chip region 61 is a region that is cut from the semiconductor wafer 60 along the scribe line 62 by a dicing blade or the like and becomes a semiconductor chip (semiconductor substrate 11). A width w1 of each of the scribe lines 62 of the semiconductor wafer 60 is, for example, about 200 μm.

First, as depicted in FIGS. 5 and 6, the semiconductor wafer 60 is fabricated by growing, by epitaxy, the epitaxial layer 22 that constitutes the n⁻-type drift region 42 on a front surface of an n⁺-type starting wafer 63 that becomes the n⁺-type drain region 41. Next, by photolithography and ion implantation, diffused regions containing dopants of a predetermined conductivity type are selectively formed having the same structure at the front (surface on the epitaxial layer 22 side) side of the semiconductor wafer 60 in each chip region 61 (step S1: first step). In the process at step S1, for example, the p-type base regions 45, the n⁺-type source regions 46, the base contact regions 47 and 48, the n-type current spreading region 43, the p⁺-type regions 44, the p-type outer peripheral region 55, the p⁺-type outer peripheral contact region 56, the voltage withstanding structure 30 (the p-type regions 31 and the p⁺-type regions 32), and the channel stopper region 33 are formed in each chip region 61.

Next, the dopant ions implanted into the semiconductor wafer 60 are electrically activated by a heat treatment (activation annealing) (step S2). Here, while a case where one session of activation annealing is collectively performed after all the ion implantation steps is described as an example, the activation annealing may be performed each time each ion implantation step is performed. The order in which the diffused regions are formed in the process at step S1 may be set as appropriate. Next, the trenches (gate trenches) 49 are formed by photolithography and etching (step S3). Next, the field oxide film 34 is deposited (formed) on the entire front surface of the semiconductor wafer 60 by, for example, a chemical vapor deposition (CVD) method under normal pressure or reduced pressure (step S4: second step).

Next, an etching mask 71 is formed on the field oxide film 34. The etching mask 71 has openings 71a exposing portions corresponding to the active region 1 of each chip region 61 and openings 71b exposing portions corresponding to the scribe lines 62. Next, the field oxide film 34 is selectively removed by etching using the etching mask 71 as a mask thereby leaving the field oxide film 34 only in the outer peripheral portion of each chip region 61 excluding the active region 1 (step S5: second step). The field oxide film 34 may extend toward the center of each chip region 61 so as to cover the outer peripheral portion 1b of the active region 1 in each chip region 61. In this case, portions of the front surface of the semiconductor wafer 60 are exposed in the center portion 1a of the active region 1 and the scribe lines 62 in each chip region 61. Subsequently, the etching mask 71 is removed.

Next, as depicted in FIG. 7, the gate insulating film 50 is formed along the inner walls of the trenches 49 by, for example, a CVD method under normal pressure or reduced pressure, a high temperature oxide (HTO) method, or a thermal oxidation method (step S6: second step). At this time, the gate insulating film 50 is also formed on the exposed portions of the front surface of the semiconductor wafer 60 and the surface of the field oxide film 34. Next, a polysilicon layer (doped polysilicon layer) to which a dopant such as phosphorus (P) or boron (B) is added is deposited (formed) on the gate insulating film 50 by, for example, a CVD method so as to be embedded in the trenches 49. Then, the polysilicon layer is partially removed by photolithography and etching thereby leaving only portions constituting the gate electrodes 51 in the trenches 49, whereby the gate electrodes 51 are formed on the gate insulating film 50 in the trenches 49 (step S7).

Next, the interlayer insulating film 52 is deposited (formed) on the entire front surface of the semiconductor wafer 60 so as to cover the gate electrodes 51 by, for example, a CVD method under normal pressure or reduced pressure (step S8: second step). Next, the contact holes 52a and 52b penetrating through the interlayer insulating film 52 and the gate insulating film 50 in the depth direction are formed by photolithography and etching (step S9). Next, the interlayer insulating film 52 is planarized by a heat treatment (reflow) (step S10). The field oxide film 34, the gate insulating film 50, and the interlayer insulating film 52 formed in a portion excluding the active region 1 in each chip region 61 of the semiconductor wafer 60 constitute the insulating layer 12. The gate insulating film 50 and the interlayer insulating film 52 formed on the scribe lines 62 of the semiconductor wafer 60 constitute the insulating layer 13 having the thickness t2, which is thinner than the thickness t1 of the insulating layer 12.

The thicknesses t1 and t2 of the insulating layers 12 and 13 are obtained in advance by, for example, experiment, simulation, or the like so that the magnitude of the unbalance of the stress between the front side and the back side of the semiconductor wafer 60 after the process at step S11 described later is reduced. The thicknesses of the interlayer insulating film 52 and the field oxide film 34 may be set according to the thicknesses t1 and t2 of the insulating layers 12 and 13. The thickness t2 of the insulating layer 13 may be adjusted by an additional step of etching performed only to the insulating layer 13 at any timing after the process at step S6 but before the process at step S11 to make the thickness t2 of the insulating layer 13 substantially constant or further reduce the thickness t2 of the insulating layer 13. The etching of the field oxide film 34, the gate insulating film 50, and the interlayer insulating film 52 (the processes at steps S5 and S9 and the additional process for adjusting the thickness t1 of the insulating layer 13) may be dry etching or wet etching.

Next, a barrier metal 53 serving as the source electrode and the surface electrode 54 are deposited (formed) in this order on the front surface of the semiconductor wafer 60 by a sputtering method, a vapor deposition method, or the like, and the source electrode is patterned by photolithography and etching to be left in the active region 1 of each chip region 61. The surface electrode 57 constituting the drain electrode is formed on the entire back surface of the semiconductor wafer 60 (the back surface of the n⁺-type starting wafer 63) by a sputtering method, a vapor deposition method, or the like (step S11). For example, using the n⁺-type starting wafer 63 having a thickness exceeding the predetermined thickness of the n⁺-type drain region 41, the semiconductor wafer 60 may be thinned to a product thickness used for the semiconductor device 10 by grinding the semiconductor wafer 60 from the back surface (back surface grinding) after the process at step S10 but before the process at step S11 to thin the n⁺-type starting wafer 63 to the predetermined thickness.

Since the thickness t2 of the insulating layer 13 is smaller than the thickness t1 of the insulating layer 12 in at least a part of the insulating layer 13 on the front surface of the semiconductor wafer 60 during the process at step S11, the stress applied to the front side of the semiconductor wafer 60 by the insulating layers 12 and 13 may be reduced. This makes it possible to reduce the magnitude of the stress imbalance between the front side and the back side of the semiconductor wafer 60 after the process at step S11 (that is, the deposition of the front surface electrodes 54 and 57 and the patterning of the surface electrode 54). Therefore, even when the semiconductor wafer 60 convexly protrudes and is warped in either direction of the front side or the back side after the process at step S11, the warpage amount of the semiconductor wafer 60 may be reduced as compared with the case of manufacturing the semiconductor device 110 (see FIG. 8) of the reference example.

Specifically, as described above, in the fabrication of the semiconductor device 110 of the reference example, the warpage amount of the semiconductor wafer after the formation of the front surface electrodes (deposition of the front surface electrodes on both main surfaces of the semiconductor wafer and patterning of the front surface electrodes 131) was about 150 μm. On the other hand, by applying the method of manufacturing the semiconductor device 10 according to the present embodiment, it has been confirmed experimentally by the present inventors that the warpage amount of the semiconductor wafer 60 after the process at step S11 becomes 100 μm or less (for example, about 60 μm). Further, it has been confirmed experimentally by the present inventors that, by applying the method of manufacturing the semiconductor device 10 according to the present embodiment, the range in which the warpage amount is maximum in the plane of the semiconductor wafer 60 after the process at step S11 may be reduced as compared with the case of manufacturing the semiconductor device 110 (see FIG. 8) of the reference example.

Next, a surface protective film (passivation film: not depicted) made of an organic insulator such as polyimide is formed as the uppermost layer on the front surface of the semiconductor wafer 60. The surface protective film is formed on the entire front surface of the semiconductor wafer 60 and covers the surface electrode 54, the gate pad, and the interlayer insulating film 52 (insulating layers 12 and 13). Next, by photolithography and etching, an opening for exposing each electrode pad (a portion to be a source pad of the surface electrode 54, a gate pad (not depicted), and the like) and openings for exposing the scribe lines 62 are formed in the surface protective film. The surface protective film and the openings thereof may be formed at any timing after the formation of the surface electrode 54 but before the process at step S12 described later. As a result, the uppermost layer of the front surface of the semiconductor wafer 60 in the scribe lines 62 becomes the insulating layer 13.

Next, a protective tape is attached to each of the back surface of the semiconductor wafer 60 (the surface of the surface electrode 57) and the outer peripheral portion of the semiconductor wafer 60 to cover the entire back surface and the end portion of the semiconductor wafer 60 with the protective tape. Next, a plating film (not depicted) is formed on the surface of the surface electrode 54 by, for example, an electrolytic plating process or an electroless plating process (step S12). By the process at step S12, a plating film is formed on the metal (electrode pad) surface exposed in the opening of the surface protective film. The plating film is formed by stacking, for example, a nickel (Ni) plating film and a gold (Au) plating film in this order. Thereafter, the semiconductor wafer 60 is diced (cut) along the scribe lines 62 by a dicing blade or the like, and the respective chip regions 61 of the semiconductor wafer 60 are separated into individual semiconductor chips (semiconductor substrates 11) (step S13: third step).

For example, the chip regions 61 are arranged in a matrix-like pattern on the semiconductor wafer 60, and the scribe lines 62 are formed in a lattice- shaped pattern surrounding the peripheries of all the chip regions 61 (see FIG. 5). Therefore, the remaining portions of the scribe lines 62 of the semiconductor wafer 60 remain as the residual scribe region 3 at the entire outer periphery of the semiconductor substrate 11 of the individual chip regions 61 cut from of the semiconductor wafer 60. In the residual scribe region 3, the insulating layer 13 remains on the front surface of the semiconductor substrate 11 and has the thickness t2, which is smaller than the thickness t1 of the insulating layer 12. Since portions of the front surface (semiconductor surface) of the semiconductor wafer 60 in the scribe lines 62 are covered by the insulating layer 13, contamination due to processing debris, adhesion of a plating film, or the like on the front surface of the semiconductor substrate 11 in the residual scribe region 3 does not occur. Thus, the semiconductor device 10 of FIGS. 1 to 3 is completed.

As described above, according to the embodiment, the thickness of the insulating layer covering the front surface of the semiconductor wafer in the scribe lines is made thinner than the thickness of the insulating layer covering the front surface of the semiconductor wafer in the outer peripheral portion of each chip region of the semiconductor wafer. Since the stress applied to the front side of the semiconductor wafer is reduced by the insulating layer on the front surface of the semiconductor wafer, the magnitude of the imbalance in stress between the front side and the back side of the semiconductor wafer after the formation of the front surface electrode may be reduced. Thus, even when the semiconductor wafer after the formation of the front surface electrode is warped so as to protrude and curve in either direction of the front side and the back side, the amount of warpage is small, and the warpage of the semiconductor wafer is reduced so that the semiconductor wafer may be brought close to a substantially flat state, or the warpage of the semiconductor wafer is relaxed so that the semiconductor wafer may be brought into a substantially flat state.

By reducing or relaxing the warpage of the semiconductor wafer, it is possible to suppress the occurrence of problems due to the warpage of the semiconductor wafer (transport failure of the semiconductor wafer, chucking (suction attachment) failure of the semiconductor wafer to the stage of the semiconductor manufacturing equipment, decreased alignment accuracy, increased thickness variation of the deposited film, and the like) in the subsequent manufacturing process. Thus, even when the semiconductor wafer is warped, the subsequent manufacturing process may be continued without discarding the semiconductor wafer, so that the yield of products (semiconductor devices) may be improved. Further, according to the embodiment, since only the thickness of the insulating layer on the front surface of the semiconductor wafer in the scribe line needs to be appropriately set, it is possible to reduce or relax the warpage of the semiconductor wafer while maintaining the chip area (the surface area of the chip region). In addition, since the chip area is maintained, the number of semiconductor chips per semiconductor wafer is maintained.

In addition, for example, in a case where an existing semiconductor device (for example, a semiconductor device of a reference example: see FIG. 8) includes an insulating layer formed by stacking multiple insulating films on the front surface of the semiconductor substrate in the edge termination region and a portion corresponding to the active region of the chip region of the semiconductor wafer is removed by selectively etching any insulating film (for example, a field oxide film) of the insulating films constituting the insulating layer in the manufacturing method of the existing semiconductor device, a portion of the insulating film on the scribe line is also removed at the same time, so that the residual scribe region of the existing semiconductor device may have the same structure as the residual scribe region of the semiconductor device according to the embodiment. Therefore, according to the embodiment, the semiconductor device according to the embodiment may be manufactured by changing only the pattern of the etching mask of the insulating film without increasing the number of steps by applying the existing method of manufacturing a semiconductor device.

As described above, the present disclosure is not limited to the above-described embodiments, and various modifications may be made without departing from the spirit of the present disclosure. For example, in the above- described embodiments, while a semiconductor device including the surface electrodes on both main surfaces of the semiconductor substrate has been described as an example, the present disclosure may be applied to a semiconductor device including a surface electrode only on the front surface of the semiconductor substrate. In addition, in the above-described embodiments, while the structure in which the three insulating films (the field oxide film, the gate insulating film, and the interlayer insulating film) are stacked on the front surface of the semiconductor substrate in the edge termination region is adopted, the number of stacked insulating films may be appropriately set, and may be increased or decreased. The material of the semiconductor substrate may be Si.

The semiconductor device and the method of manufacturing a semiconductor device achieve an effect in that yield may be improved.

As described above, the semiconductor device and the method for manufacturing the semiconductor device according to the present disclosure are useful for a semiconductor device fabricated (manufactured) on a thin semiconductor substrate (semiconductor chip) in which warpage is likely to occur due to stress received from a deposited film (electrode layer or insulating layer) on a main surface of the semiconductor substrate, and are particularly suitable for a semiconductor device using SiC as a semiconductor material.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device comprising:
a semiconductor substrate, having:
an active region through which a main current flows, and
a termination region surrounding a periphery of the active region, and having a residual scribe region at an outer periphery of the semiconductor substrate, in a plan view of the semiconductor device,
the semiconductor substrate having a main surface;
a channel stopper region provided in the semiconductor substrate, at the main surface, the channel stopper being closer to the active region than is the residual scribe region;
a first insulating layer provided on the main surface of the semiconductor substrate in the termination region, closer to the active region than is the residual scribe region, the first insulating layer covering the channel stopper region; and
a second insulating layer provided on the main surface of the semiconductor substrate in the termination region, the second insulating layer being in the residual scribe region, the second insulating layer being thinner than the first insulating layer.

2. The semiconductor device according to claim 1, wherein a thickness of the second insulating layer is 1/2 or less of a thickness of the first insulating layer.

3. The semiconductor device according to claim 1, wherein the thickness of the second insulating layer is not more than 8000Å.

4. The semiconductor device according to claim 1, wherein the channel stopper region has an outer peripheral end that is located at an inner peripheral end of the residual scribe region.

5. The semiconductor device according to claim 1, further comprising a voltage withstanding structure provided in the semiconductor substrate, at the main surface in the termination region, apart from the channel stopper region and closer to the active region than is the channel stopper region, wherein
the first insulating layer covers the voltage withstanding structure and the channel stopper region.

6. A method of manufacturing a semiconductor device including, in a semiconductor substrate,
an active region through which a main current flows, and
a termination region surrounding a periphery of the active region in a plan view of the semiconductor device,
the method comprising:
providing a semiconductor wafer having a chip region, for forming therein the active region and the termination region;
forming a channel stopper region in the semiconductor wafer, at a main surface of the semiconductor wafer, the channel stopper region being formed in a region corresponding to the termination region of the chip region;
forming an insulating layer on the main surface of the semiconductor wafer; and
cutting the semiconductor wafer along a scribe line surrounding a periphery of the chip region to thereby cut the chip region from the semiconductor wafer and form the semiconductor substrate, wherein
the forming the insulating layer includes forming a first insulating layer covering the channel stopper region and a second insulating layer covering the scribe line, and
a thickness of the second insulating layer is smaller than a thickness of the first insulating layer.

7. The method of manufacturing according to claim 6, wherein the forming the insulating layer includes stacking a plurality of insulating films on the first main surface of the semiconductor wafer, the first insulating layer being constituted by all the stacked plurality of insulating films and the second insulating layer being constituted by a portion of the stacked plurality of insulating films.
